(19) United States
(12) Patent Application Publication
(10) Pub. No.: US 2008/0047600 A1
(43) Pub. Date: Feb. 28, 2008

(54) PHOTOELECTRIC CONVERSION ELEMENT AND PROCESS THEREOF

(75) Inventors: Yoshihiro Ohashi, Tokyo (JP); Toru Den, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/780,104

(22) Filed: Jul. 19, 2007

(30) Foreign Application Priority Data
Aug. 28, 2006 (JP) 2006-230570

(51) Int. Cl. H01L 31/04; H01L 21/02; H01L 31/0224

(52) U.S. Cl. 136/255; 438/92; 257/E21.002

(57) ABSTRACT

A photoelectric conversion element has a Schottky electrode, a light-receiving semiconductor layer in contact with the Schottky electrode, and a transparent electrode in contact with the light-receiving semiconductor layer, wherein the Schottky electrode has a periodic concavo-convex structure; the light-receiving semiconductor layer is placed in contact with a face of the concavo-convex structure of the Schottky electrode; and the concavo-convex height of the concavo-convex structure of the Schottky electrode ranges from 1/20 to ⅕ of the periodic distance of the concavo-convex structure.

### BACKGROUND OF THE INVENTION

1. Field of the Invention

The present invention relates to a Schottky barrier type of photoelectric conversion element.

2. Description of the Related Art

Some of the photoelectric conversion elements for converting a light energy into an electric energy employ a pn junction or a p-i-p junction of a semiconductor, or employ a Schottky junction of a semiconductor with a metal like those of solar cells. Single crystal silicon type solar cells, polycrystalline silicon solar cells, and amorphous silicon type solar cells are commercialized. Generally, for higher efficiency of the photoelectric conversion element, the light-absorbing semiconductor layer is made thicker to obtain a longer optical path in the layer. For use as the solar cell, however, the larger thickness of the light-absorbing layer results in a heavy weight of the solar cell owing to the large surface area of the layer, and requires a larger amount of the construction material. Therefore, for lighter weight of the photoelectric conversion element and resource saving, the conversion efficiency of the photoelectric conversion element should be improved.

In one method for increasing the efficiency of the photoelectric conversion, surface plasmon induced on a metal surface is utilized. The surface plasmon which is induced on the metal surface is localized in a small region at or near the metal surface and generates an electric field intensified by a factor ranging from tens to hundreds in comparison with the electric field produced by light introduced therein. In a light-receiving semiconductor layer placed near the metal surface having the induced surface plasmon, a large amount of the carrier can be excited by the intensified electric field to increase the conversion efficiency. The surface plasmon is classified into two types: a propagating surface plasmon and a localized surface plasmon. The propagating surface plasmon is induced by attenuated total reflection (ATR) or a periodic surface structure of the metal. The localized surface plasmon is induced by metal fine particles having a closed surface.

A light-receiving element of a Schottky barrier type having a concavo-convex structure on a metal surface is disclosed which has a concavo-convex structure on a metal silicide of a Schottky electrode (Japanese Patent Application Laid-Open No. 2000-164918). The height difference and pitches (periodic distance) of the concavo-convex structure are nearly equal to or less than the average free path of the hot carriers traversing the Schottky barrier: specifically about 10 nm or less.

A light-receiving element containing metal fine particles therein is disclosed (Japanese Patent application Laid-Open No. 2006-066550). In this element, an optical energy penetrating through a photoelectric conversion layer is converted by the metal fine particles in the element into an enhanced electric field of localized surface plasmon to produce further an electric energy to improve the conversion efficiency.

In the disclosure in the above Japanese Patent Application Laid-Open No. 2000-164918, the concavo-convex height and concavo-convex pitch in the concavo-convex structure are defined to be not more than the mean free path of the hot carriers. For inducing the propagating surface plasmon, the concavo-convex structure should have the periodic distance (pattern pitch) in the range of the light wavelength. Therefore, the surface plasmon cannot be induced by such a structure.

In the disclosure of the above-mentioned Japanese Patent Application Laid-Open No. 2006-066550, metal fine particles for producing the localized type surface plasmon are disposed in contact with the photoelectric conversion layer. When the electric energy generated in the photoelectric conversion layer is taken out from this element through the metal fine particles, energy loss is caused owing to the high contact resistance between the layer and the metal fine particles. For collecting efficiently the electric energy generated in the photoelectric conversion layer, a contact region is necessary between the photoelectric conversion layer and an electrode. For utilizing enhanced electric field induced by metal fine particles, the photoelectric conversion layer is preferably connected with the metal fine particles in the entire region. However, this decreases the contact region between the photoelectric conversion layer and the electrode to increase the electric resistance disadvantageously. On the other hand, an increase of the region of the contact between the photoelectric conversion layer and the electrode to decrease the electric resistance results in decrease with the metal fine particles to make difficult to achieve the effect of the enhanced electric field.

### SUMMARY OF THE INVENTION

The present invention intends to provide a Schottky barrier type of photoelectric conversion element having a Schottky electrode in an improved electrode shape for higher efficiency, and to provide a process for producing the photoelectric conversion element.

The present invention is directed to a photoelectric conversion element having a Schottky electrode, a light-receiving semiconductor layer in contact with the Schottky electrode, and a transparent electrode in contact with the light-receiving semiconductor layer, wherein the Schottky electrode has a periodic concavo-convex structure; the light-receiving semiconductor layer is placed in contact with a face of the concavo-convex structure of the Schottky electrode; and the concavo-convex height of the concavo-convex structure of the Schottky electrode ranges from 1/20 to ⅕ of the periodic distance of the concavo-convex structure.

The periodic distance of the concavo-convex structure can range from 300 nm to 1200 nm.

The width of the convex of the Schottky electrode can range from ¼ to ¾ of the periodic distance of the concavo-convex structure.

The periodic arrangement of the periodic concavo-convex structure of the Schottky electrode can be in a periodic pattern of dots, lines, or concentric circles.

The Schottky electrode can be made of any of gold, silver, aluminum, copper, and platinum.

The present invention is directed to a process for producing a photoelectric conversion element comprising a first step of forming a Schottky electrode, a second step of forming a light-receiving semiconductor layer on the Schottky electrode, and a third step of forming a transparent electrode on the light-receiving semiconductor layer, wherein the first step of forming the Schottky electrode comprises marking pore formation points arranged regularly on an aluminum-containing substrate surface, anodizing the substrate to form pores, forming as structure on the substrate and in the pores, and eliminating the substrate to obtain the Schottky electrode having a concavo-convex configuration in accordance with the shape of the pores; and the second step of forming the light-receiving semiconductor layer comprises forming the light-receiving semiconductor layer on the face having the concavo-convex structure of the Schottky electrode.

The present invention is directed to a process for producing a photoelectric conversion element comprising a first step of forming a Schottky electrode, a second step of forming a light-receiving semiconductor layer on the Schottky electrode, and a third step of forming a transparent electrode on the light-receiving semiconductor layer, wherein the first step of forming the Schottky electrode comprises formation of a concavo-convex structure on the Schottky electrode by photolithography; and the second step of forming the light-receiving semiconductor layer comprises formation the light-receiving semiconductor layer on the face the concavo-convex structure of the Schottky electrode.

The present invention provides a Schottky barrier type of photoelectric conversion element of high conversion efficiency.

Further features of the present invention will become apparent from the following description of exemplary embodiments with reference to the attached drawings.

### BRIEF DESCRIPTION OF THE DRAWINGS

FIG. 1A is a schematic plan view of a photoelectric conversion element of the present invention. FIG. 1B is a schematic plan view thereof.

FIG. 2 is a graph showing dependence of a reinforced electric field on a concavo-convex height.

FIG. 3 is a graph showing dependence of a resonance wavelength on a periodic distance P of the concavo-convex structure.

FIGS. 4A and 4B illustrate schematically a relation between a resonance mode and a localized electric field.

FIGS. 5A, 5B, 5C, 5D and 5E illustrate schematically periodic arrangement patterns of concavo-convex electrodes of photoelectric conversion elements of the present invention. The upper parts of the respective drawings are sectional views and the lower parts of the respective drawings are plan views.

FIGS. 6A, 6B, 6C, 6D, 6E and 6F illustrate a process for production of the photoelectric element of the present invention.

### DESCRIPTION OF THE EMBODIMENTS

The photoelectric conversion element of the present invention is described below in detail on reference to the drawings.

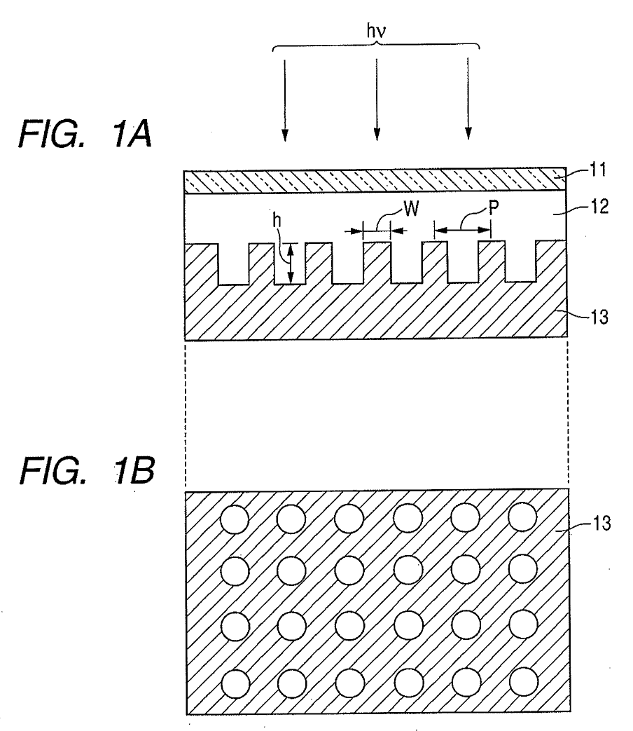

The light-receiving semiconductor element of the present invention is of a Schottky barrier type. On reference to FIGS. 1A and 1B, the light-receiving semiconductor element comprises a Schottky electrode 13 having a periodic concavo-convex structure (projection-depression pattern) for producing surface plasmon; a light-receiving semiconductor layer 12 placed in contact with the concavo-convex face of the electrode; and a transparent electrode 11 placed in contact with the light-receiving semiconductor layer. The concavo-convex height of the Schottky electrode is characteristically in the range from 1/20 to ⅕ of the concavo-convex periodic distance. The concavo-convex height of the Schottky electrode of 1/20 to ⅕ of the concavo-convex periodic distance enables generation of a reinforced electric field both on the convex top faces and in the concavo-convex gaps of the concavo-convex structure. Thereby, the light-receiving semiconductor layer placed in contact with the concavo-convex electrode can be entirely excited. The resulting Schottky barrier type light-receiving semiconductor element achieves a higher conversion efficiency.

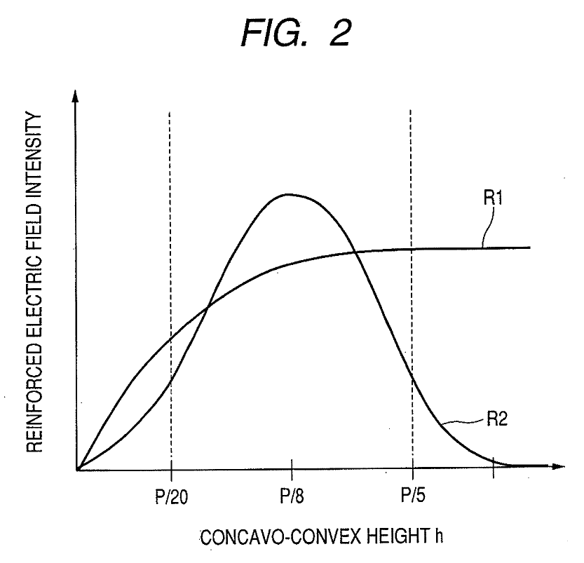

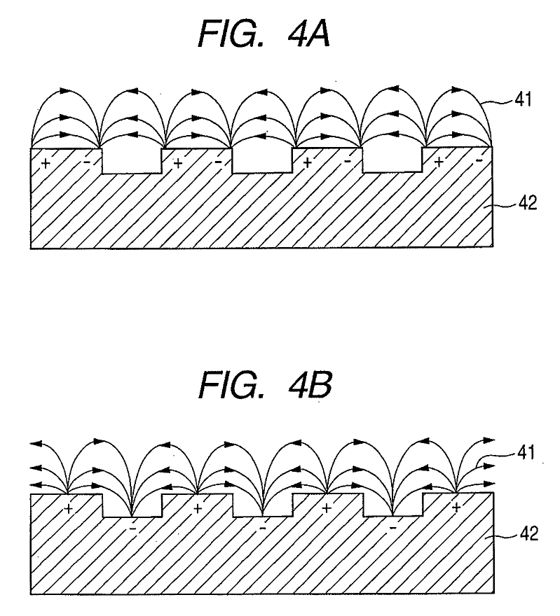

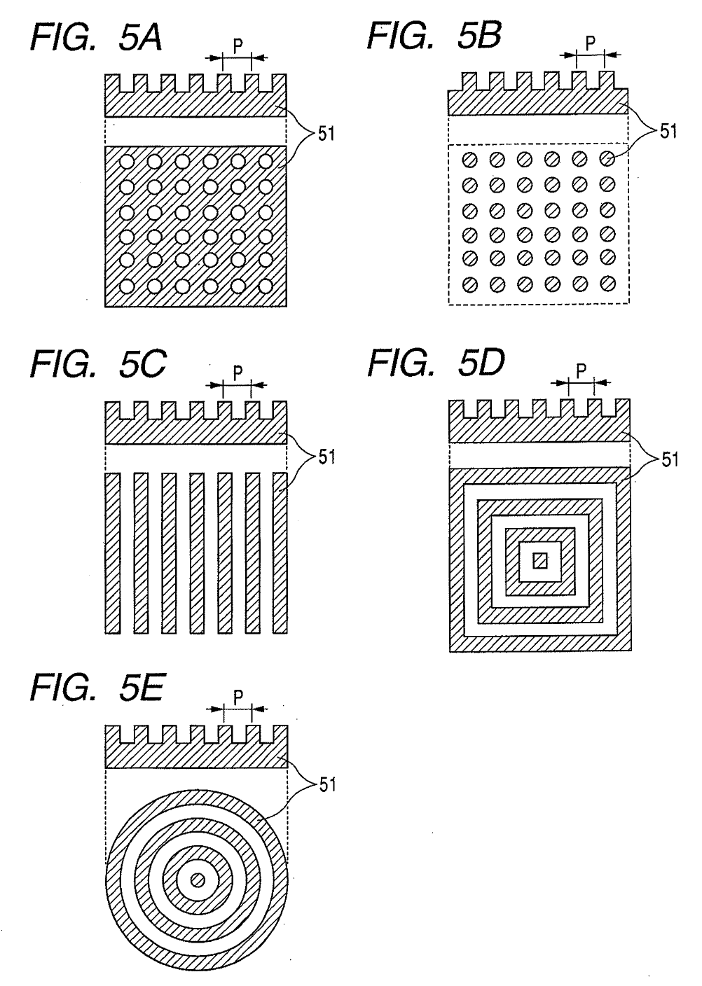

When a light beam is introduced to a metal film surface having a periodic concavo-convex structure as illustrated in FIGS. 1A, 1B and FIGS. 5A to 5E, the light is scattered by the concavo-convex structure and generates a compression wave of free electrons, namely surface plasmon, at the metal surface to form a reinforced electric field near the surface of the metal concavo-convex structure in comparison with the electric field generated by the incident light. The region where electric field is concentrated by the surface plasmon is called “a hot site”. In particular, in a periodic concavo-convex structure formed on the metal film surface as illustrated in FIGS. 1A, 1B and FIGS. 5A to 5E, two modes of the resonance can be induced to form respectively a hot site in separate regions. The intensities of the respective resonance modes depend on the concavo-convex height h. One mode of the formed resonance produces a reinforced electric field connecting the metal top edges as illustrated in FIG. 4A: This resonance mode is hereinafter referred to as “resonance-1”. The other mode of the formed resonance produces a localized electric field connecting the concave bottoms and convex tops as illustrated in FIG. 4B: This resonance mode is hereinafter referred to as “resonance-2”. The resonance-1 has the hot sites near the convex top end face, particularly at the top end edge of the concavo-convex structure. The resonance-2 has the hot sites between the bottoms of the concaves and the tops of the convexes of the concavo-convex structure of the electrode. FIG. 2 shows dependence of the reinforced electric field intensity on the concavo-convex height h when silver is employed as the concavo-convex metal electrode and Si is employed as the contacting light-receiving semiconductor layer. In FIG. 2, the curve R1 and the curve R2 shows respectively the dependence of the electric field caused by the resonance-1 and the resonance-2. The intensity of the reinforced electric field produced by resonance-1 increases with increase of the height h, becomes saturated at the height h of ⅕ of the periodic distance of the concavo-convex structure of the electrode not to be affected by the height increase: At the height h of zero, where the metal surface is flat, the surface plasmon is not induced. With increase of the height h, the surface plasmon comes to be induced to produce higher intensity of the reinforced electric field. At the height h larger further, the reinforced electric field intensity is saturated since the height is approximated by an infinite length of a hole. Therefore, for formation of a strongly excited resonance-1, the concavo-convex structure is made to have height h of 1/20 of the periodic distance P or more. On the other hand, the resonance-2 produces a reinforced electric field depending greatly on the height h. At the height h of approximately zero, where the metal surface is nearly flat, the surface plasmon is not induced similarly as the resonance-1. With increase of the height h, the surface plasmon comes to be induced to produce higher intensity of the reinforced electric field. At the height h of about ⅛ of the periodic distance P. the reinforced electric field intensity reaches the maximum. At a further larger height h, the reinforced electric field intensity comes to decrease to zero. This is because the resonance-2 is caused to form a localized electric field connecting the bottoms and tops of the concavo-convex structure. At an extremely larger height, the electric field connecting the bottoms and the tops cannot be produced. Therefore, the concavo-convex height h should be within a certain range suitable for producing the resonance-2.

The light energy is converted to a photoelectric current by exciting the semiconductor light-receiving layer by two processes in the present invention. In one process, the light introduced from the top side of the element excites directly the semiconductor light-receiving layer 12 to generate a photoelectric current (hereinafter referred to as “Process-1”). In the other process, the light which is not absorbed and penetrates through light-receiving layer 12 produces a reinforced electric field caused by the surface plasmon of resonance-1 and resonance-2 on concavo-convex electrode 13 to excite semiconductor light-receiving layer 12 to generate the photoelectric current (this process is hereinafter referred to as “Process-2”). The detected photoelectric current is the total of the currents generated by Process-1 and Process-2. With a completely flat electrode (i.e., H=0), the surface plasmon is not induced and the photoelectric current generated by Process-1 only is detected. With an electrode of h>0, surface plasmon is induced and the excitation by Process 2 occurs. At the height h relatively small in comparison with P (0<h<P/2), the surface plasmon is induced little to produce the weakly reinforced electric field. In this case, the absolute intensity of the photoelectric current produced by Process-2 is low in comparison with that produce by Process-1, and the significant effect of the concavo-convex structure of the electrode is not reflected on the photoelectric current intensity. At a lager height h, larger than 1/20 of the periodic distance of the concavo-convex structure of the electrode, the increase of the photoelectric current caused by the surface plasmon induction by Process-2 becomes significant as the detected photoelectric current. At the height h of about P/8, the intensity of the resonance-2 reaches the maximum to give the maximum increase of the detected photoelectric current. At a larger height h, the resonance-2 becomes weaker, and becomes, at h=P/5 or larger, a further significant increase of the photoelectric current is not detected. Therefore, the significant increase of the photoelectric current by the surface plasmon is detected in the range of P/20<h<P/5 where the surface plasmon is induced both by resonance-1 and by resonance-2. From the above reason, in the present invention, the concavo-convex height of the concavo-convex structure of the electrode is preferably in the range of 1/20 to ⅕ of the periodic distance P of the concavo-convex structure of the electrode. More preferably the height h is ⅛ of the periodic distance P of the concavo-convex structure of the electrode.

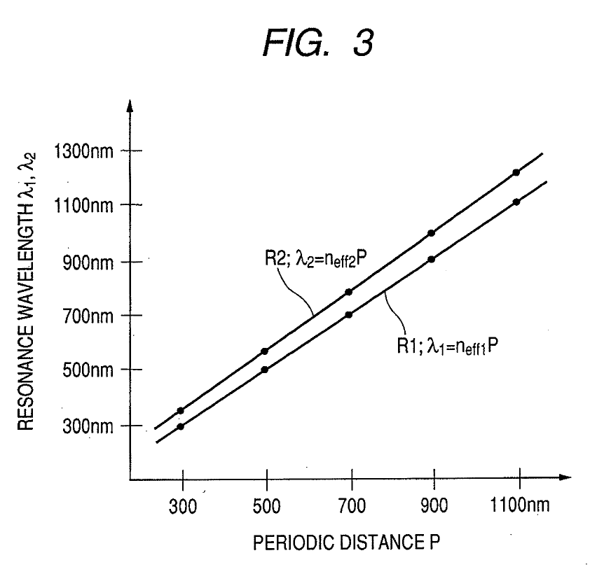

Simultaneous excitation of the two modes of the resonances, namely resonance-1 and resonance-2, gives the plasmon resonance in a broader wavelength range in comparison with the excitation of resonance-1 only. The reason is described below. The resonance wavelengths of resonance-1 and resonance-2 are represented herein respectively by λ₁ and λ₂. For a low order of resonance modes, λ₁=n_{eff1}P, and λ₂=n_{eff2}P, where n_{eff1} and n_{eff2} denote respectively an effective refraction index. Generally, n_{eff}=[∈ₘ∈_{d}/(∈ₘ+∈_{d})]^{1/2}, where ∈ₘ denotes the dielectric constant of a metal, and ∈_{d} denotes the dielectric constant of an adjacent layer. However, the resonance-2 which penetrates deeper into the metal electrode has the effective refractive index shifted slightly to that of the metal. That is, n_{eff1}<n_{eff2}. Therefore, λ₁<λ₂. Thus the resonance-2 has resonance wavelength longer than that of resonance-1. FIG. 3 shows the dependence of λ₁ and λ₂ on the periodic distance P. Owing to the difference in the resonance wavelength between the resonance-1 and the resonance-2, simultaneous excitation in two resonance modes gives the resonance in broader wavelength range than that caused by excitation of resonance-1 only.

The present invention converts a light energy into an electric field by sensing incident light by an electrode having a concavo-convex structure having a periodic distance P corresponding to the wavelength of the incident light. For forming a surface plasmon resonance with light having the wavelength in the range from visible light to near infrared light, the electrode has preferably a periodic distance ranging form 300 nm to 1200 nm. As shown in FIG. 3, the resonance wavelength can be changed arbitrarily in the range from visible light to infrared light by changing the periodic distance P of the concavo-convex structure of the adjacent layer.

The resonance-1 forms a reinforced electric field connecting the top edges of the convexes of the metal. With the convex width W smaller than ¼ of the periodic distance P of the concavo-convex structure, the reinforced electric field connecting the top edges of the concavo-convex metal electrode is hardly formed owing to the excessively small widths of the convex tops, resulting in a remarkably weak reinforced electric field produced by the resonance-1. Therefore, the width W of the convexes of the concavo-convex electrode is preferably not smaller than ¼ of the periodic distance P of the concavo-convex structure. On the other hand, the resonance-2 forms a reinforced electric field connecting the top face of the convexes and the bottoms of the concaves of the concavo-convex metal electrode. Therefore, with the width W of the convexes larger than ¾ of the periodic distance P of the concavo-convex structure, the reinforced electric field connecting the top faces of the convexes and the bottoms of the concaves of the concavo-convex electrode is hardly formed owing to the excessively small widths of the concaves to lower remarkably the reinforced electric field produced by the resonance-2. Therefore, the width W of the convexes of the concavo-convex electrode is preferably not larger than ¾ of the periodic distance P of the concavo-convex structure. With the width W of the convexes of ½ of the periodic distance P in the concavo-convex structure, the edges of the convexes of the electrode are placed at regular intervals, so that the resonance-1 and the resonance-2 are both formed in the maximum intensity. Therefore, the width of the convexes of the concavo-convex electrode is preferably in the range from ¼ to ¾, more preferably ½ of the periodic distance P of the concavo-convex structure.

The convexes of the concavo-convex electrode are arranged preferably in patterned dots, concentric circles, parallel lines, or polygons. FIGS. 5A to 5E illustrate examples of the concavo-convex patterns on the surface of the concavo-convex metal electrodes: (a) a pattern of holes in a dot arrangement (FIG. 5A); (b) a pattern of projections (FIG. 5B); (c) a pattern of parallel lines (FIG. 5C); (d) a pattern of polygons (FIG. 5D); and (e) a pattern of concentric circles (FIG. 5E). For exciting the surface plasmon, polarized light should be employed which has the polarization plane of the incident light to meet the pattern shape. With the dot arrangement of the above patterns (a) and (b), low-order to high-order of resonances are excited along the periodic distance direction. With the line pattern (c), the surface plasmon can be excited by the light polarized in a direction along the pattern, but cannot be excited by the light polarized in a different direction. With the polygonal pattern (d), the surface plasmon can be excited by the light polarized in a direction of one side of the polygon. With the concentric circle pattern, the resonance can be excited by any incident light of random polarization like sunlight. The surface plasmon can be strongly excited when the convexes has sharp edges like that having a rectangular or square cross-section. However, the shape of the concavo-convex structure is not limited in the present invention: the convexes may be conical, or convex edges may be rounded.

For excitation of a strong surface plasmon, the concavo-convex electrode is preferably made of any of gold, silver, aluminum, copper, and platinum.

Next, the process for producing the photoelectric conversion element of the present invention is described below. Firstly, a Schottky electrode is prepared. On a surface of a substrate containing aluminum, pore-formation points are marked. Secondary, the substrate is anodized to form pores at the marked points. On the substrate having the pores, a structure is formed for a Schottky electrode. Then the substrate is removed to obtain a Schottky electrode having the convexo-convex structure reflecting the shape of the pores of the substrate. On the concavo-convex face of the Schottky electrode, a light-receiving semiconductor layer is formed by sputtering or a like method to form a Schottky junction. Finally, on the light-receiving semiconductor layer, a transparent electrode is formed to complete a photoelectric conversion element of the present invention. The concavo-convex Schottky electrode may be produced through other process than the anodization such as photolithography.

### EXAMPLES

The present invention is described specifically below with examples without limiting the invention.

### Example 1

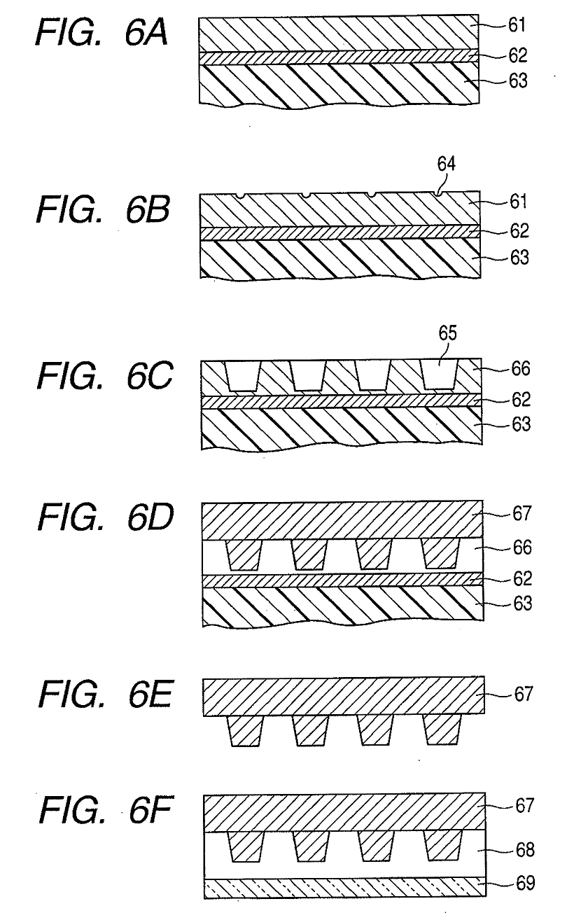

A photoelectric conversion element of the present invention is produced which has an electrode of a concavo-convex structure formed by utilizing pores formed by anodization. The process for production of the photoelectric conversion element of this Example is described in detail with reference to FIGS. 6A to 6F. The process comprises the steps (a) to (f) corresponding to FIGS. 6A to 6F.

(a) Aluminum Thin Film Formation Step

On Si substrate 63, an electroconductive film (Ti) is formed as underlayer 62 in a thickness of 5 nm. Thereon, aluminum thin film 61 containing additional metal (at least one of Ti, Cr, Zr, Nb, Mo, Hf, Ta, and W) is formed in a thickness of 100 nm.

(b) Pore Formation Point Marking Step

On the aluminum thin film 61, pore formation points 64 are engraved by FIB (focused ion beam) processing machine by using Ga ions, under the processing conditions: acceleration voltage of 30 kV, ionic current of 3 pA, and irradiation time of 10 milliseconds for one pore formation point, in a square lattice pattern at point intervals of 400 nm. The pore formation points may be marked by another method such as stamping with a stamper, and electron beam lithography. The pattern of the pore formation points 64 may be selected arbitrarily to prepare a concavo-convex electrode 67 having periodic arrangement of points, lines, or concentric circles.

(c) Pore Formation Step

Aluminum thin film 61 is anodized by an anodization apparatus. Thereby aluminum thin film 61 is converted to anodized oxide film 66 and pores 65 are formed at the positions of the marked pore formation points 64 in the direction perpendicular to the substrate. The anodization is conducted with aqueous 0.3M oxalic acid solution as the acidic electrolyte at a temperature of 3° C. in a thermostatic bath at an anodization voltage of 40 V. After the anodization, the thin film is treated for pore-widening to enlarge the pore diameter by immersion in a 5-wt % phosphoric acid solution for 30 minutes to enlarge the pore diameter and to eliminate protrusions on the pore walls to make the pore walls smooth. The formed pores 65 have a pore diameter of 200 nm, pore intervals of 400 nm, and pore depth of 50 nm. The pore depth can be changed by selecting the anodization conditions. The pore diameter can be changed by selecting the pore-widening conditions.

(d) Concavo-Convex Electrode Formation Step

Into the pores 65, silver is filled by plating as portions of concavo-convex electrode 67. After the filling of the silver, the plating with silver is further continued to cover the anodized oxide film 66 to complete concavo-convex electrode 67. The filling of the metal by plating may be conducted by electrolytic plating, or non-electrolytic plating; or by sputtering.

(e) Concavo-Convex Electrode Separation Step

After the plating, anodized oxide film 66 is etched by 10-wt % NaOH to obtain concavo-convex electrode 67. The concavo-convex pattern of the electrode has a periodic distance P of 400 nm, a convex width W of 200 nm, and a concavo-convex height h of 50 nm.

(f) Element Formation Step

Onto concavo-convex silver electrode 67 prepared as above, p-type Si layer 68 is deposited in a thickness of 400 nm by sputtering to form a Schottky conjunction with the concavo-convex electrode 67. Thereon ITO is deposited as transparent electrode 69 to complete the element.

The photoelectric conversion element produced as above is capable of generating a photoelectric current of an intensity higher by 0.5% or more than that generated by a conventional photoelectric conversion element having no concavo-convex structure of the electrode.

### Example 2

In this Example, photolithography is employed for forming the concavo-convex structure of the Schottky electrode. The process for production of the photoelectric conversion element of this Example is described below.

On a silver electrode, a negative type of photoresist is applied. The photoresist is exposed to light through a pattern mask of a square lattice having holes of 200 nm diameter and hole interval of 400 nm, and is developed. The pores are formed in the electrode by etching to a pore depth of 50 nm. Finally the remaining resist is eliminated to obtain a silver electrode having a square concavo-convex pattern having a pore diameter of 200 nm, pore intervals of 400 nm, and a pore depth of 50 nm. On the resulting concavo-convex silver electrode, p-type Si is deposited in a thickness of 400 nm by sputtering to form a Schottky junction with the silver electrode. Thereon ITO is deposited as the upper transparent electrode to complete the photoelectric conversion element.

The photoelectric conversion element produced above is capable of generating a photoelectric current of an intensity higher by 0.5% or more than that generated by a conventional photoelectric conversion element having no concavo-convex structure of the electrode.

The present invention is applicable to photoelectric conversion elements such as solar cells, and infrared light sensors.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-230570, filed Aug. 28, 2006, which is hereby incorporated by reference herein in its entirety.

What is claimed is:

1. A photoelectric conversion element having a Schottky electrode, a light-receiving semiconductor layer in contact with the Schottky electrode, and a transparent electrode in contact with the light-receiving semiconductor layer, wherein the Schottky electrode has a periodic concavo-convex structure; the light-receiving semiconductor layer is placed in contact with a face of the concavo-convex structure of the Schottky electrode; and the concavo-convex height of the concavo-convex structure of the Schottky electrode ranges from 1/20 to ⅕ of the periodic distance of the concavo-convex structure.

2. The photoelectric conversion element according to claim 1, wherein the periodic distance of the concavo-convex structure ranges from 300 nm to 1200 nm.

3. The photoelectric conversion element according to claim 1, wherein the width of the convex of the Schottky electrode ranges from ¼ to ¾ of the periodic distance of the concavo-convex structure.

4. The photoelectric conversion element according to claim 1, wherein the periodic arrangement of the periodic concavo-convex structure of the Schottky electrode is in a periodic pattern of dots, lines, or concentric circles.

5. The photoelectric conversion element according to claim 1, wherein the Schottky electrode is made of any of gold, silver, aluminum, copper, and platinum.

6. A process for producing a photoelectric conversion element comprising a first step of forming a Schottky electrode, a second step of forming a light-receiving semiconductor layer on the Schottky electrode, and a third step of forming a transparent electrode on the light-receiving semiconductor layer, wherein the first step of forming the Schottky electrode comprises marking pore formation points arranged regularly on an aluminum-containing substrate surface, anodizing the substrate to form pores, forming as structure on the substrate and in the pores, and eliminating the substrate to obtain the Schottky electrode having a concavo-convex configuration in accordance with the shape of the pores; and the second step of forming the light-receiving semiconductor layer comprises forming the light-receiving semiconductor layer on the face having the concavo-convex structure of the Schottky electrode.

7. A process for producing a photoelectric conversion element comprising a first step of forming a Schottky electrode, a second step of forming a light-receiving semiconductor layer on the Schottky electrode, and a third step of forming a transparent electrode on the light-receiving semiconductor layer, wherein the first step of forming the Schottky electrode comprises formation of a concavo-convex structure on the Schottky electrode by photolithography; and the second step of forming the light-receiving semiconductor layer comprises formation the light-receiving semiconductor layer on the face the concavo-convex structure of the Schottky electrode.
